(19) United States
(12) Patent Application Publication
(10) Pub. No.: US 2006/0207652 A1
(43) Pub. Date: Sep. 21, 2006

(54) Polymer photovoltaic cell

(76) Inventors: Christoph Brabec, Linz (AT); Alan Heeger, Santa Barbara, CA (US); Markus Scharber, Linz (AT)

Correspondence Address: FISH & RICHARDSON PC, P.O. BOX 1022, MINNEAPOLIS, MN, 55440-1022, US

(21) Appl. No.: 11/364,307

(22) Filed: Feb. 28, 2006

Related U.S. Application Data
(60) Provisional application No. 60/663,985, filed on Mar. 21, 2005.
(60) Provisional application No. 60/687,088, filed on Jun. 2, 2005.

(51) Int. Cl. H01L 31/00

(52) U.S. Cl. 136/263

(57) ABSTRACT

Polymer photovoltaic cells, as well related modules and methods, are disclosed.

### CROSS REFERENCE TO RELATED APPLICATIONS

Pursuant to 35 U.S.C. § 119(e), this application claims priority to U.S. Provisional Application Ser. No. 60/663,985, filed Mar. 21, 2005, and to U.S. Provisional Application Ser. No. 60/687,088, filed Jun. 2, 2005, the contents of which are hereby incorporated by reference.

### TECHNICAL FIELD

This invention relates to polymer photovoltaic cells, as well as related modules and methods.

### BACKGROUND

Polymer photovoltaic cells may be used to convert solar energy to electrical energy. Such cells generally include a photoactive layer that contains an electron donor material and an electron acceptor material.

### SUMMARY

This invention relates to polymer photovoltaic cells, as well as related modules and methods.

In one aspect, this invention features a method that includes selecting an electron donor material having a highest occupied molecular orbital (HOMO) energy level with respect to vacuum, E_{HOMO}^{Do}, for use in a photovoltaic cell. The E_{HOMO}^{Do} is obtained based upon a selected efficiency of the photovoltaic cell, a selected fill factor of the photovoltaic cell, a selected short circuit current of the photovoltaic cell, and a selected electron acceptor material for use in the photovoltaic cell.

In another aspect, this invention features a method of preparing a photovoltaic cell. The method includes selecting an electron donor material having an E_{HOMO}^{Do} and disposing the electron donor material between two electrodes.

In still another aspect, this invention features a method that includes selecting an electron acceptor material, selecting an electron donor material having an E_{HOMO}^{Do}, and disposing the electron acceptor material and the electron donor material between two electrodes.

In still another aspect, this invention features a method that includes: (1) selecting an electron donor material having a band gap of at most about 2.5 eV and a lowest unoccupied molecular orbital (LUMO) energy level with respect to vacuum, E_{LUMO}^{Do}, and an electron acceptor material having a LUMO energy level with respect to vacuum, E_{LUMO}^{Ac}, in which the difference between the E_{LUMO}^{Do} and the E_{LUMO}^{Ac} is at most about 1.2 eV, and (2) disposing the electron donor material and the electron acceptor material between two electrodes.

In a further aspect, this invention features a photovoltaic cell that includes a first electrode, a second electrode, and an active layer disposed between the first and second electrodes. The active layer includes an electron donor material having an E_{HOMO}^{Do} and an electron acceptor material. The electron donor material and the electron acceptor material are such that the efficiency of the photovoltaic cell, η, is at least about 3% calculated based upon equation (1):
η=(1/|e|)·(−E_{HOMO}^{Do}−C)·FF·I_{sc}/I_{light} (1)
in which FF is a selected fill factor of the photovoltaic cell, I_{sc} is a selected 'short circuit current of the photovoltaic cell, I_{light} is the incident light intensity, e is the charge of an electron, and C is a constant based upon the selected electron acceptor material. FF can be calculated from the following equation: FF=(Iₘ×Vₘ)/(I_{sc}×V_{oc}), in which Iₘ and Vₘ respectively refer to the current and voltage at the maximum power output, I_{sc} refers to the current produced by a photovoltaic cell with a shorted output, and V_{oc} refers to the voltage produced by a photovoltaic cell with no external load.

In still a further aspect, this invention features a photovoltaic cell that includes two electrodes and an active layer disposed between the two electrodes. The active layer includes an electron donor material and an electron acceptor material. The electron donor material has a band gap of at most about 2.5 eV and has an E_{LUMO}^{Do}. The electron acceptor material has an E_{LUMO}^{Ac}. The difference between the E_{LUMO}^{Do} and the E_{LUMO}^{Ac} is at most about 1.2 eV.

In yet a further aspect, this invention features a module that includes a plurality of photovoltaic cells (e.g., one or more of the forgoing photovoltaic cells). At least some of the photovoltaic cells are electrically connected (e.g., some of the cells are connected in series and/or some of the cells are connected in parallel).

Embodiments can include one or more of the following features.

E_{HOMO}^{Do} can be obtained using equation (I) based upon a selected efficiency of the photovoltaic cell, a selected fill factor of the photovoltaic cell, a selected short circuit current of the photovoltaic cell, and a selected electron acceptor material. For example, E_{HOMO}^{Do} can be at most about −5 eV (e.g., at most about −5.5 eV or at most about −6 eV).

The efficiency of the photovoltaic cell, η, can be at least about 3% (e.g., at least about 4% or at least about 5%).

The constant C in equation (I) can be at most about 5 eV (e.g., at most about 4 eV or at most about 3 eV). 1 5 The electron acceptor material can be C61-phenyl-butyric acid methyl ester (PCBM).

The band gap of the electron donor material, E_{g}, can be at most about 2.2 eV (e.g., at most about 2.0 eV or at most about 1.5 eV).

The difference between E_{LUMO}^{Do} and E_{LUMO}^{Ac}, ΔE, can be at most about 1.0 eV (e.g., at most about 0.8 eV) or at least about 0.3 eV.

Other features and advantages of the invention will be apparent from the description, drawings, and claims.

### DESCRIPTION OF DRAWINGS

FIG. 1 is a cross-sectional view of an embodiment of a photovoltaic cell.

FIG. 2 is an exemplary plot showing the correlation between E_{HOMO}^{Do} of an electron donor material and V_{oc} of a photovoltaic cell.

FIG. 3 is an exemplary plot showing the correlation between the band gap of the electron donor material, E_{g}, the difference between E_{LUMO}^{Do} and E_{LUMO}^{Ac}, ΔE, and the efficiency, η, of a photovoltaic cell.

Like reference symbols in the various drawings indicate like elements.

### DETAILED DESCRIPTION

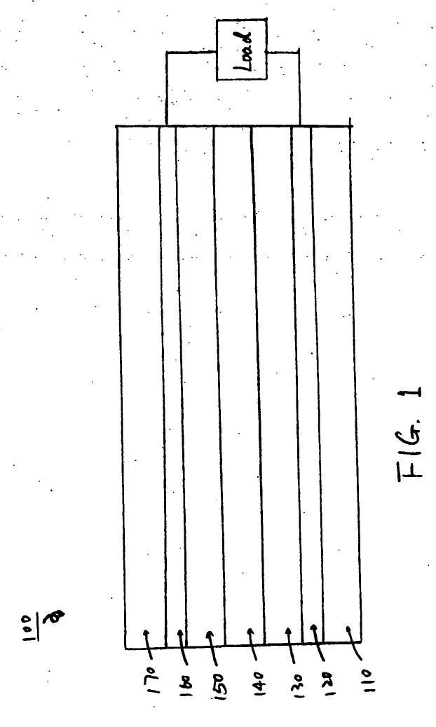

FIG. 1 shows a cross-sectional view of a photovoltaic cell 100 that includes a substrate 110, a cathode 120, a hole carrier layer 130, an active layer 140 (containing an electron acceptor material and an electron donor material), a hole blocking layer 150, an anode 160, and a substrate 170.

In general, during use, light impinges on the surface of substrate 110, and passes through substrate 110, cathode 120, and hole carrier layer 130. The light then interacts with active layer 140, causing electrons to be transferred from the electron donor material to the electron acceptor material. The electron acceptor material then transmits the electrons through hole blocking layer 150 to anode 160, and the electron donor material transfers holes through hole carrier layer 130 to cathode 120. Anode 160 and cathode 120 are in electrical connection via an external load so that electrons pass from anode 160, through the load, and to cathode 120.

With respect to active layer 140, the electron donor material has a HOMO energy level with respect to vacuum, E_{HOMO}^{Do}, and a LUMO energy level with respect to vacuum, E_{LUMO}^{Do}. The band gap of the electron donor material, E_{g}, can be calculated from the equation: E_{g}=E_{LUMO}^{Do}−E_{HOMO}^{Do}. Similarly, the electron acceptor material in active layer 140 has a HOMO energy level with respect to vacuum, E_{HOMO}^{Ac}, and a LUMO energy level with respect to vacuum, E_{LUMO}^{Ac}. The difference between E_{LUMO}^{Do} and E_{LUMO}^{Ac}, ΔE, can be calculated from the equation: ΔE=E_{LUMO}^{Do}−E_{LUMO}^{Ac}. Without wishing to be bound by theory, it is believed that a photovoltaic cell having a desired efficiency can be prepared by selecting the electron acceptor material and electron donor material based on these parameters. Such methods are described below.

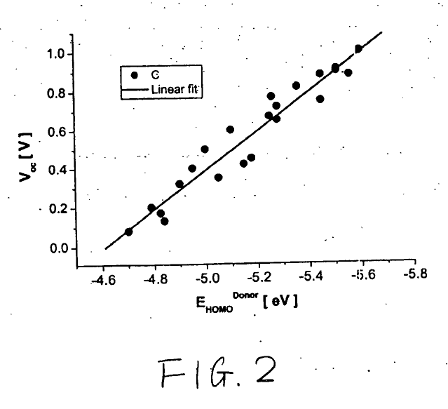

FIG. 2 is an exemplary plot showing the correlation between E_{HOMO}^{Do} of a electron donor material and open circuit voltage, V_{oc}, of photovoltaic cell 100 that contains PCBM as an electron acceptor material. According to the FIG. 2, V_{oc} of the photovoltaic cell is in general linearly proportional to E_{HOMO}^{Do} of an electron donor material. This linear correlation can be shown by a solid line that best fits the data points in FIG. 2 and can be expressed by equation (2):
V_{oc}=(1/|e|)·(−E_{HOMO}^{Do}−C) (2)
in which e is the charge of an electron and C is a constant based on a selected electron acceptor material. The value of C can be obtained by extrapolating the solid line in FIG. 2 to the point where V_{oc} is 0 mV. For example, for the data represented in FIG. 2, C is 4.6 eV. This linear correlation can vary depending upon, for example, different electron acceptor materials used.

The efficiency of photovoltaic cell 100, η, can generally be calculated by equation (3):
η=V_{oc}·FF·I_{sc}/I_{light} (3)
in which FF is a selected fill factor of photovoltaic cell 100, I_{sc} is a selected short circuit current of photovoltaic cell 100, and I_{light} is the incident light intensity. Substituting V_{oc} obtained from equation (2) for V_{oc} in equation (3) results in equation (1):
η=(1|e|)·(−E_{HOMO}^{Do}−C)·FF·I_{sc}/I_{light} (1)

Equation (1) can be solved to predict E_{HOMO}^{Do} of an electron donor material to be used in photovoltaic cell 100 having a desired efficiency. For example, E_{HOMO}^{Do} can be calculated by the following five steps: (1) selecting an electron acceptor material to determine C, (2) selecting an E_{g} for an electron donor material, (3) calculating I_{sc}, (4) selecting an FF and an η, and (5) calculating E_{HOMO}^{Do} by solving equation (1). These five steps can be in different sequences and are described in more detail below: As mentioned above, C is a constant based on the selected electron acceptor material. For example, after selecting an electron acceptor material, C can be obtained from a plot prepared in a manner similar to FIG. 2. At a given E_{g}, I_{sc} can be calculated from equation (4):

$${I}_{SC} = {\int }_{0}^{λg} {n}_{AM 1.5} ( λ ) \cdot EQE ( λ ) \cdot ⅆ λ \qquad ( 4 )$$

in which λ is the wavelength of the incident light arriving at photovoltaic cell 100, n_{AM 1.5} (λ) is the number of photons arriving at photovoltaic cell 100 per a unit area under AM 1.5 illumination as a function of λ, EQE (λ) is the external quantum efficiency of photovoltaic cell 100 as a function of λ, and λ_{g} is the longest wavelength of the incident light absorbed by the electron donor material. The function between n_{AM 1.5} and λ can be obtained empirically. To simplify equation (4), EQE(λ) can be set at a typical value for a polymer photovoltaic cell, such as 0.65. λ_{g} can be calculated from the equation λ_{g}=h·c/E_{g} (in which h is the Plank constant and c is the speed of light) and is a constant for a pre-determined E_{g} of the electron donor material. After EQE(λ) and λ_{g} are set to predetermined values, I_{sc} can be calculated from equation (4) by solving the integration of function n_{AM} 1.5 (λ) and is also a constant. To simplify equation (1), FF can be set at a typical value for a polymer photovoltaic cell, such as 0.65. Thus, after selecting a pre-determined η, one can obtain a value of E_{HOMO}^{Do} by substituting the pre-determined η, C, FF, and I_{sc} in equation (1). Note that, assuming EQE(λ) is kept at the same value, I_{sc} varies depending upon the E_{g} for the electron donor material used. Thus, by using a different E_{g} to calculate different λ_{g} in equation (4), one can obtain a different value of E_{HOMO}^{Do} from equation (1).

Photovoltaic cell 100 having a desired efficiency can then be prepared by using the pre-determined electron acceptor material and an electron donor material having the pre-determined E_{g} and the E_{HOMO}^{Do} calculated from equation (1).

In general, to achieve a given minimum efficiency in a photovoltaic cell, there is a corresponding maximum value for E_{g} and, independently, a corresponding maximum value for ΔE. Thus, photovoltaic cell 100 having a desired efficiency can also be prepared by using an electron acceptor material and an electron donor material such that each of E_{g} of the electron donor material and ΔE is smaller than a suitable value. A method of determining suitable E_{g} and ΔE is described below.

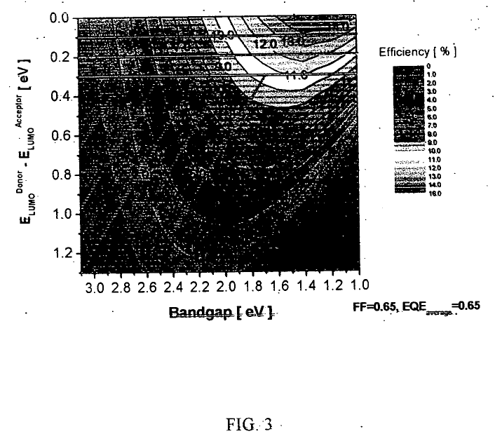

FIG. 3 is an exemplary plot derived from equation (1). It shows the correlation between the band gap of the electron donor material, E_{g}, the difference between E_{LUMO}^{Do} and E_{LUMO}^{Ac}, ΔE, and the efficiency, η, of photovoltaic cell 100 that contains PCBM as an electron acceptor material. FIG. 3 can be derived according to the following steps: (1) One can select a desired electron acceptor material, e.g., PCBM. (2) FF in equation (1) and EQE(λ) in equation (4) can both be set at a typical value for a photovoltaic cell, e.g., 0.65. (3) One can pick an E_{g} to be used to derive FIG. 3. Based the selected E_{g}, one can obtain the value of the corresponding λ_{g} and then use it to obtain the value of the short circuit current, I_{sc}, based on equation (4). (4) One can pick an E_{LUMO}^{Do} value to obtain a ΔE value using equation ΔE=E_{LUMO}^{Do}−E_{LUMO}^{Ac} and an n value using equation (1). Step (4) can be repeated for different E_{LUMO}^{Do} values. One can then repeat steps (3) and (4) for different E_{g}. Subsequently, FIG. 3 can be derived based on the values of η, E_{g}, and ΔE obtained above.

As shown in FIG. 3, there are numerous pairs of values of E_{g} and ΔE that result in a given efficiency. The data points on each solid line in FIG. 3 have the same efficiency value. To achieve a given efficiency, both E_{g} and ΔE can be smaller than a suitable value. For example, assuming ΔE is at least 0.3 eV and at most 0.9 eV, to achieve an efficiency of 5%, E_{g} can at most be about 2.5 eV and ΔE can at most be about 0.9 eV. Thus, assuming ΔE is at least 0.3 eV and at most 0.9 eV, photovoltaic cell 100 having an efficiency of at least 5% can be prepared by using an electron donor material having an E_{g} of less than about 2.5 eV. The correlation shown in FIG. 3 can vary depending upon, for example, different FF, EQE (λ), and electron acceptor materials used.

Examples of suitable electron donor materials include one or more of polyacetylene, polyaniline, polyphenylene, poly(p-phenylene vinylene), polythienylvinylene, polythiophene, polyporphyrins, porphyrinic macrocycles, polymetallocenes, polyisothianaphthalene, polyphthalocyanine, a discotic liquid crystal (e.g., a discotic liquid crystal polymer), and a derivative or a combination (e.g., a copolymer or a blend of two or more of just-described polymers or copolymers) thereof. Exemplary derivatives of the electron donor materials include derivatives having pendant groups, e.g., a cyclic ether, such as epoxy, oxetane, furan, or cyclohexene oxide. Derivatives of these materials may alternatively or additionally include other substituents. For example, thiophene components of electron donor may include a phenyl group, such as at the 3 position of each thiophene moiety. As another example, alkyl, alkoxy, cyano, amino, and/or hydroxy substituent groups may be present in any of the polyphenylacetylene, polydiphenylacetylene, polythiophene, and poly(p-phenylene vinylene) conjugated polymers. In certain embodiments, active layer 140 can include a combination of electron donor materials.

Examples of suitable electron acceptor materials include substituted and/or unsubstituted fullerenes, oxadiazoles, carbon nanorods, discotic liquid crystals, inorganic nanoparticles (e.g., nanoparticles formed of zinc oxide, tungsten oxide, indium phosphide, cadmium selenide and/or lead sulphide), inorganic nanorods (e.g., nanorods formed of zinc oxide, tungsten oxide, indium phosphide, cadmium selenide and/or lead sulphide), or polymers containing moieties capable of accepting electrons or forming stable anions (e.g., polymers containing CN groups, polymers containing CF₃ groups).

Generally, active layer 140 is sufficiently thick to be relatively efficient at absorbing photons impinging thereon to form corresponding electrons and holes, and sufficiently thin to be relatively efficient at transporting the holes and electrons to electrodes of the device. In certain embodiments, layer 140 is at least 0.05 micron (e.g., at least about 0.1 micron, at least about 0.2 micron, or at least about 0.3 micron) thick and/or at most about 1 micron (e.g., at most about 0.5 micron or at most about 0.4 micron) thick. In some embodiments, layer 140 is from about 0.1 micron to about 0.2 micron thick.

Turning now to other components of photovoltaic cell 100, substrate 110 is typically formed of a transparent material. As referred to herein, a transparent material is a material, which, at the thickness used in a photovoltaic cell 100, transmits at least about 60% (e.g., at least about 70%, at least about 75%, at least about 80%, or at least about 85%) of incident light at a wavelength or a range of wavelengths used during operation of the photovoltaic cell. An exemplary wavelength or range of wavelengths occurs between about 300 nanometers and about 850 nanometers.

Exemplary materials from which substrate 110 can be formed include polyethylene terephthalates, polyimides, polyethylene naphthalates, polymeric hydrocarbons, cellulosic polymers, polycarbonates, polyamides, polyethers, polyether ketones, and derivatives thereof including copolymers of such materials. In certain embodiments, the polymer can be a fluorocarbon, e.g., a fluorocarbon ether. In some embodiments, combinations of polymeric materials are used. In certain embodiments, different regions of substrate 110 can be formed of different materials.

In general, substrate 110 can be flexible, semi-rigid, or rigid (e.g., glass). In some embodiments, substrate 110 has a flexural modulus of less than about 5,000 megaPascals. In certain embodiments, different regions of substrate 110 can be flexible, semi-rigid, or inflexible (e.g., one or more regions flexible and one or more different regions semi-rigid, or one or more regions flexible and one or more different regions inflexible).

Typically, substrate 110 is at least about I micron (e.g., at least about 5 microns or at least about 10 microns) thick and/or at most about 1,000 microns (e.g., at most about 500 microns thick, at most about 300 microns thick, at most about 200 microns thick, at most about 100 microns, or at most about 50 microns) thick.

Generally, substrate 110 can be colored or non-colored. In some embodiments, one or more portions of substrate 110 is/are colored while one or more different portions of substrate 110 is/are non-colored.

Substrate 110 can have one planar surface (e.g., the surface on which light impinges), two planar surfaces (e.g., the surface on which light impinges and the opposite surface), or no planar surfaces. A non-planar surface of substrate 110 can, for example, be curved or stepped. In some embodiments, a non-planar surface of substrate 110 is patterned (e.g., having patterned steps to form a Fresnel lens, a lenticular lens or a lenticular prism).

Either or both of cathode 120 and anode 160 may be configured to transmit at least a portion of light impinging thereon. For example, at least one of cathode 120 and anode 160 may be formed of a transmissive material. An exemplary transmissive material includes a transmissive oxide, such as a tin oxide, e.g., indium-doped tin oxide (ITO). As an alternative to or in conjunction with a transmissive material, cathode 120 may be configured with open areas to allow light to pass through and closed areas defined by a conductive material that conducts electrons. In one embodiment, at least one of cathode 120 and anode 160 is a mesh. Photovoltaic cells having mesh electrodes are disclosed, for example, in co-pending and commonly owned U.S. Utility applications Ser. Nos. 10/395,823, 10/723,554, and 10/494,560, each of which is hereby incorporated by reference.

Hole carrier layer 130 is generally formed of a material that, at the thickness used in photovoltaic cell 100, transports holes to electrode 120 and substantially blocks the transport of electrons to electrode 120. Examples of materials from which layer 130 can be formed include polythiophenes (e.g., poly(3,4-ethylenedioxythiophene)), polyanilines, polyvinylcarbazoles, polyphenylenes, polyphenylvinylenes, polysilanes, polythienylenevinylenes and/or polyisothianaphthanenes. In some embodiments, hole carrier layer 130 can include combinations of hole carrier materials.

In general, the distance between the upper surface of hole carrier layer 130 (i.e., the surface of hole carrier layer 130 in contact with photoactive layer 140) and the upper surface of electrode 120 (i.e., the surface of electrode 120 in contact with hole carrier layer 130) can be varied as desired. Typically, the distance between the upper surface of hole carrier layer 130 and the upper surface of electrode 120 is at least 0.01 micron (e.g., at least about 0.05 micron, at least about 0.1 micron, at least about 0.2 micron, at least about 0.3 micron, or at least about 0.5 micron) and/or at most about 5 microns (e.g., at most about 3 microns, at most about 2 microns, or at most about 1 micron). In some embodiments, the distance between the upper surface of hole carrier layer 130 and the upper surface of electrode 120 is from about 0.01 micron to about 0.5 micron.

Hole blocking layer 150 is generally formed of a material that, at the thickness used in photovoltaic cell 100, transports electrons to anode 160 and substantially blocks the transport of holes to anode 160. Examples of materials from which layer 150 can be formed include LiF and metal oxides (e.g., zinc oxide, titanium oxide).

Typically, hole blocking layer 150 is at least 0.02 micron (e.g., at least about 0.03 micron, at least about 0.04 micron, or at least about 0.05 micron) thick and/or at most about 0.5 micron (e.g., at most about 0.4 micron, at most about 0.3 micron, at most about 0.2 micron, or at most about 0.1 micron) thick.

Substrate 170 can be formed of a transparent material or a non-transparent material. For example, in embodiments in which a photovoltaic cell uses light that passes through anode 160 during operation, substrate 170 is desirably formed of a transparent material. Substrate 170 can be either identical to or different from substrate 110 mentioned above. Generally, substrate 170 is substantially non-scattering.

In some embodiments, a photovoltaic cell can be prepared as follows. Anode 160 is formed on substrate 170 using conventional techniques, and hole-blocking layer 150 is formed on anode 160 (e.g., using a vacuum deposition process or a solution coating process). Active layer 140 is formed on hole-blocking layer 150 using a suitable process, such as, ink jet printing, spin coating, dip coating, knife coating, bar coating, spray coating, roller coating, slot coating, gravure coating, or screen printing. Hole carrier layer 130 is formed on active layer 140 using, for example, a solution coating process. Cathode 120 is partially disposed in hole carrier layer 130 (e.g., by disposing cathode 120 on the surface of hole carrier layer 130, and pressing cathode 120). Substrate 110 is then formed on cathode 120 and hole carrier layer 130 using conventional methods.

This invention also features a photovoltaic module that includes a plurality of photovoltaic cells. At least some of the photovoltaic cells are electrically connected. The photovoltaic module can generally be used as a component in any intended systems. Examples of such systems include roofing, package labeling, battery chargers, sensors, window shades and blinds, awnings, opaque or semitransparent windows, and exterior wall panels.

U.S. Provisional Patent Application Ser. No. 60/663,985, filed Mar. 21, 2005, is hereby incorporated by reference.

The following examples are illustrative and not intended to be limiting.

### EXAMPLES

23 electron donor materials were tested for evaluating the correlation between the E_{HOMO}^{Do} of an electron donor material and the V_{oc} of a corresponding photovoltaic cell prepared from it. Specifically, 10 mg of an electron donor material and 10 mg of PCBM were dissolved in xylene, and deposited on a structured glass-ITO-Baytron PH substrate. A LiF layer and an aluminum layer were subsequently deposited by evaporation as a top-electrode. Details on the cell preparation can be found in Padinger et al. Adv. Functl. Mat., 2003, 13, p. 1. The E_{HOMO}^{Do} of each electron donor material was measured by cyclovoltametry. The V_{oc} of the photovoltaic cell containing each electron donor material was measured by source-measure unit Keithley 2400 while the solar cell was illuminated under 800 W/m² AM 1.5 condition. The measured correlation between V_{oc} and E_{HOMO}^{Do} for the cells is shown in FIG. 2.

Other embodiments are in the claims.

What is claimed is:

1. A method, comprising:
selecting an electron donor material having a HOMO energy level with respect to vacuum, E_{HOMO}^{Do}, for use in a photovoltaic cell, wherein E_{HOMO}^{Do} is obtained based upon a selected efficiency of the photovoltaic cell, a selected fill factor of the photovoltaic cell, a selected short circuit current of the photovoltaic cell, and a selected electron acceptor material for use in the photovoltaic cell.

2. The method of claim 1, wherein E_{HOMO}^{Do} is obtained using equation (1):
η=(1/|e|)·(−E_{HOMO}^{Do}−C)·FF·I_{sc}/I_{light} (1),
in which η is the selected efficiency of the photovoltaic cell, FF is the selected fill factor of the photovoltaic cell, I_{sc} is the selected short circuit current of the photovoltaic cell, I_{light} is the incident light intensity, e is the charge of an electron, and C is a constant based upon the selected electron acceptor material.

3. The method of claim 2, wherein C is at most about 5 eV.

4. The method of claim 2, wherein C is at most about 4 eV.

5. The method of claim 2, wherein C is at most about 3 eV.

6. The method of claim 2, further comprising disposing the electron donor material between two electrodes.

7. The method of claim 6, wherein C is at most about 5 eV.

8. The method of claim 1, wherein the selected efficiency is at least about 3%.

9. The method of claim 1, wherein the selected efficiency is at least about 4%.

10. The method of claim 1, wherein the selected efficiency is at least about 5%.

11. The method of claim 1, wherein E_{HOMO}^{Do} is at most about −5 eV.

12. The method of claim 1, wherein E_{HOMO}^{Do} is at most about −5.5 eV.

13. The method of claim 1, wherein E_{HOMO}^{Do} is at most about −6 eV.

14. The method of claim 1, wherein the electron acceptor material comprises PCBM.

15. The method of claim 1, further comprising disposing the electron donor material between two electrodes.

16. The method of claim 15, wherein the selected efficiency is at least about 3%.

17. The method of claim 15, wherein E_{HOMO}^{Do} is at most about −5 eV.

18. The method of claim 15, wherein the electron acceptor material comprises PCBM.

19. A method of preparing a photovoltaic cell, comprising:
selecting an electron acceptor material;
selecting an electron donor material having a HOMO energy level with respect to vacuum, E_{HOMO}^{Do}, wherein E_{HOMO}^{Do} is obtained based upon a selected efficiency of the photovoltaic cell, a selected fill factor of the photovoltaic cell, a selected short circuit current of the photovoltaic cell, and the selected electron acceptor material; and
disposing the electron acceptor material and the electron donor material between two electrodes.

20. The method of claim 19, wherein E_{HOMO}^{Do} is obtained using equation (1):
η=(1/|3|)·(−E_{HOMO}^{Do}−C)·FF·I_{sc}/I_{light} (1),
in which η is the selected efficiency of the photovoltaic cell, FF is the selected fill factor of the photovoltaic cell, I_{sc} is the selected short circuit current of the photovoltaic cell, I_{light} is the incident light intensity, e is the charge, and C is a constant based upon the selected electron acceptor material.

21. A method of preparing a photovoltaic cell, comprising:
selecting an electron donor material having a band gap of at most about 2.5 eV and a LUMO energy level with respect to vacuum, E_{LUMO}^{Do}, and an electron acceptor material having a LUMO energy level with respect to vacuum, E_{LUMO}^{Ac}, wherein the difference between E_{LUMO}^{Do} and E_{LUMO}^{Ac} is at most about 1.2 eV; and
disposing the electron donor material and the electron acceptor material between two electrodes.

22. The method of claim 21, wherein the band gap of the electron donor material is at most about 2.2 eV.

23. The method of claim 21, wherein the band gap of the electron donor material is at most about 2.0 eV.

24. The method of claim 21, wherein the band gap of the electron donor material is at most about 1.5 eV.

25. The method of claim 21, wherein the difference between E_{LUMO}^{Do} and E_{LUMO}^{Ac} is at most about 1.0 eV.

26. The method of claim 21, wherein the difference between E_{LUMO}^{Do} and E_{LUMO}^{Ac} is at most about 0.8 eV.

27. The method of claim 21, wherein the difference between E_{LUMO}^{Do} and E_{LUMO}^{Ac} is at least about 0.3 eV.

28. The method of claim 21, wherein the efficiency of the photovoltaic cell, η, is at least about 3%.

29. The method of claim 21, wherein the efficiency of the photovoltaic cell, η, is at least about 4%.

30. The method of claim 21, wherein the efficiency of the photovoltaic cell, η, is at least about 5%.

31. A photovoltaic cell, comprising:
a first electrode;
a second electrode; and
an active layer disposed between the first and second electrodes, the active layer comprising an electron donor material having a HOMO energy level with respect to vacuum, E_{HOMO}^{Do}, and an electron acceptor material,
wherein an efficiency of the photovoltaic cell, η, is at least about 3% calculated based upon equation (1):
η=(1/|e|)·(−E_{HOMO}^{Do}−C)·FF·I_{sc}/I_{light} (1),
in which FF is a selected fill factor of the photovoltaic cell, I_{sc} is a selected short circuit current of the photovoltaic cell, I_{light} is the incident light intensity, e is the charge of an electron, and C is a constant based upon the selected electron acceptor material.

32. The photovoltaic cell of claim 31, wherein η is at least about 4%.

33. The photovoltaic cell of claim 31, wherein η is at least about 5%.

34. The photovoltaic cell of claim 31, wherein E_{HOMO}^{Do} is at most about −5 eV.

35. The photovoltaic cell of claim 31, wherein E_{HOMO}^{Do} is at most about −5.5 eV.

36. The photovoltaic cell of claim 31, wherein E_{HOMO}^{Do} is at most about −6 eV.

37. The photovoltaic cell of claim 31, wherein the electron acceptor material comprises PCBM.

38. The photovoltaic cell of claim 31, wherein C is at most about 5 eV.

39. The photovoltaic cell of claim 31, wherein C is at most about 4 eV.

40. The photovoltaic cell of claim 31, wherein C is at most about 3 eV.

41. A photovoltaic cell, comprising:
a first electrode;
a second electrode; and
an active layer disposed between the first and second electrodes, the active layer comprising an electron donor material and an electron acceptor material,
wherein the electron donor material has a band gap of at most about 2.5 eV and a LUMO energy level with respect to vacuum, E_{LUMO}^{Do}, and the electron acceptor material has a LUMO energy level with respect to vacuum, E_{LUMO}^{Ac}; the difference between E_{LUMO}^{Do} and E_{LUMO}^{Ac} being at most about 1.2 eV.

42. The photovoltaic cell of claim 41, wherein the band gap of the electron donor material is at most about 2.2 eV.

43. The photovoltaic cell of claim 41, wherein the band gap of the electron donor material is at most about 2.0 eV.

44. The photovoltaic cell of claim 41, wherein the band gap of the electron donor material is at most about 1.5 eV.

45. The photovoltaic cell of claim 41, wherein the difference between E_{LUMO}^{Do} and E_{LUMO}^{Ac} is at most about 1.0 eV.

46. The photovoltaic cell of claim 41, wherein the difference between E_{LUMO}^{Do} and E_{LUMO}^{Ac} is at most about 0.8 eV.

47. The photovoltaic cell of claim 41, wherein the difference between E_{LUMO}^{Do} and E_{LUMO}^{Ac} is at least about 0.3 eV.

48. The photovoltaic cell of claim 41, wherein the efficiency of the photovoltaic cell, η, is at least about 3%.

49. The photovoltaic cell of claim 41, wherein the efficiency of the photovoltaic cell, η, is at least about 4%.

50. The photovoltaic cell of claim 41, wherein the efficiency of the photovoltaic cell, η, is at least about 5%.

51. A module, comprising a plurality of the photovoltaic cells of claim 31, at least some of the photovoltaic cells being electrically connected.

52. The module of claim 51, wherein at least some of the cells are connected in series.

53. The module of claim 51, wherein at least some of the cells are connected in parallel.

54. A module, comprising a plurality of the photovoltaic cells of claim 41, at least some of the photovoltaic cells being electrically connected.

55. The module of claim 54, wherein at least some of the cells are connected in series.

56. The module of claim 54, wherein at least some of the cells are connected in parallel.
